(19) United States
(12) Patent Application Publication
(10) Pub. No.: US 2024/0408841 A1
(43) Pub. Date: Dec. 12, 2024

(54) SANDWICH STRUCTURE AND MANUFACTURING METHOD THEREOF, AND ELECTRONIC DEVICE HOUSING

(71) Applicant: TORAY INDUSTRIES, INC., Tokyo (JP)

(72) Inventors: Kentaro ADACHI, Iyo-gun (JP); Hidetoshi SAKAI, Tokyo (JP); Masato HONMA, Iyo-gun (JP)

(73) Assignee: TORAY INDUSTRIES, INC., Tokyo (JP)

(21) Appl. No.: 18/698,424

(22) PCT Filed: Oct. 18, 2022
(86) PCT No.: PCT/JP2022/038697

§ 371 Date: Apr. 4, 2024

(30) Foreign Application Priority Data
Oct. 26, 2021 (JP) 2021-174341

(51) Int. Cl. B32B 5/12; B29C 65/00; B29C 65/70; B29L 31/34; B32B 3/28; H05K 5/02

(52) U.S. Cl. CPC B32B 5/12; B32B 3/28; H05K 5/02; B29C 65/70; B29C 66/721; B29L 2031/3481; B32B 2250/03; B32B 2250/20; B32B 2250/40; B32B 2260/023; B32B 2260/046; B32B 2262/106; B32B 2307/7376; B32B 2457/00

(57) ABSTRACT

An object of the present invention is to provide a sandwich structure with excellent lightness and mechanical properties, and a member for electronic device housings. A main object of the present invention is to provide a sandwich structure including: a plate-like fiber-reinforced composite material member (core material) having a portion formed into a shape in which wavy corrugations extend unidirectionally or multidirectionally; and two plate-like fiber-reinforced composite material members (skin materials) that are bonded to the core material at tops or bottoms of the corrugation of the core material, while having interspaces between the member and the rest part of the core material, and are bonded to each other or through a part of the core material without wavy corrugations formed therein at a peripheral part of the corrugation formed in the core material, so as to seal the formed corrugation.

### TECHNICAL FIELD

The present invention relates to a sandwich structure including fiber-reinforced composite materials.

### BACKGROUND ART

A housing that constitutes an electronic device is required to have both rigidity to protect the inside of the electronic device and lightness that is advantageous to carry.

Fiber-reinforced composite materials are materials with excellent mechanical properties and lightness, and mainly used as members of aircrafts and automobiles, and have also been used as materials for electronic device housings in recent years. For example, Patent Literature 1 describes that a sandwich structure of fiber-reinforced composite materials utilizing a fiber-reinforced composite material of continuous reinforcing fibers as a skin material and a fiber-reinforced composite material of discontinuous reinforcing fibers as a core material is used as an electronic device housing. Such a sandwich structure can provide a housing with excellent bending stiffness. However, since the core material, which accounts for the majority of the weight, fills the entire space between the skin materials, there are limitation to the pursuit of lightness.

Patent Literature 2 discloses an invention in which a structure formed by three-dimensionally bending a plate-shaped fiber-reinforced composite material is used as a core material in order to improve the lightness of a sandwich structure of a fiber-reinforced composite material. Since the present structure includes many interspaces therein, the sandwich structure can be made light.

### CITATION LIST

### Patent Literature

Patent Literature 1 WO2015-029634A1
Patent Literature 2 WO2021-106649A1

### SUMMARY OF INVENTION

### Technical Problem

However, applying the sandwich structure described in Patent Literature 2 to electronic device housings may possibly cause problems such as material deterioration due to resin penetration into an opening when bonding with other members or outside air penetration into the opening. In addition, stress concentration occurs at the opening, making it easy to break, which limits the shape of the bend.

The present invention has been developed to solve the above-described problems and aims at providing a sandwich structure with excellent lightness and mechanical properties, and a member for electronic device housings.

### Solution to Problem

The present invention to solve the above-described problems is a sandwich structure, including:

a plate-like fiber-reinforced composite material member (core material) having a portion (referred to as a “core forming part”) formed into a shape in which wavy corrugations extend unidirectionally or multidirectionally and a flat plate-like portion (referred to as a “core peripheral part”) surrounding the core forming part; and

two plate-like fiber-reinforced composite material members (skin materials) that are bonded to the core material at tops or bottoms of the corrugation thereof, have interspaces between the member and the core material at the rest of the core forming part, and are bonded through a portion of the core material so as to seal to prevent the interspace adjacent to the core peripheral part from contacting with an outside air.

### Advantageous Effects of Invention

According to the present invention, a sandwich structure with excellent lightness and mechanical properties, and a member for electronic device housings can be provided.

### BRIEF DESCRIPTION OF DRAWINGS

FIG. 1 is a schematic diagram showing an example of a core material, and

FIG. 1(c) and FIG. 1(d) are partial diagrams of a core forming part extracted therefrom.

FIG. 2 is a schematic diagram for explaining the core forming part.

FIG. 3 is a schematic diagram showing an example of the orientation state of reinforcing fibers in the core material.

FIG. 4 is a schematic diagram showing an example of the sandwich structure of the present invention.

FIG. 5 is a schematic diagram showing an example of the sandwich structure of the present invention.

FIG. 6 is a schematic diagram showing an example of a cross-section of the sandwich structure of the present invention.

FIG. 7 is a schematic diagram showing an example of the shape of the core material.

FIG. 8 is a schematic diagram showing a dimension of the sandwich structure and an indenter for mechanical evaluation in Examples.

### DESCRIPTION OF EMBODIMENTS

Preferred embodiments of the present invention will be described below. For ease of understanding, the present invention will be described below with reference to the drawings as appropriate, but the present invention is not limited by these drawings.

### <Sandwich Structure>

The sandwich structure of the present invention is a sandwich structure including:

a plate-like fiber-reinforced composite material member (core material) having a portion (core forming part) formed into a shape in which wavy corrugations extend unidirectionally or multidirectionally and a flat plate-like portion (core peripheral part) surrounding the core forming part; and

two plate-like fiber-reinforced composite material members (skin materials) that are bonded to the core material at tops or bottoms of the corrugation thereof, have interspaces between the member and the core material at the rest of the core forming part, and are bonded through a portion of the core material so as to seal to prevent the interspace adjacent to the core peripheral part from contacting with an outside air.

Both the skin material and the core material of the sandwich structure in the present invention are made of fiber-reinforced composite materials. There are no particular restrictions on the reinforcing fibers used in these fiber-reinforced composite materials. For example, carbon fibers, glass fibers, aramid fibers, alumina fibers, silicon carbide fibers, boron fibers, metal fibers, natural fibers, and mineral fibers can be used, and two or more of them may be used. Among them, PAN-based, pitch-based, and rayon-based carbon fibers are preferably used from the viewpoint of high specific strength and high specific rigidity and excellent weight reduction effect. From the viewpoint of improving economy of the resulting molded article, glass fibers can be preferably used. From the viewpoint of balancing mechanical properties and economy, it is also a preferred embodiment to use carbon fibers and glass fibers together. In addition, from the viewpoint of enhancing shock absorption of the resulting molded article, aramid fibers can be preferably used. From the viewpoint of balancing mechanical properties and shock absorption, it is also a preferred embodiment to use carbon fibers and aramid fibers together. Alternatively, from the viewpoint of enhancing electrical conductivity of the resulting molded article, reinforcing fibers coated with metal such as nickel, copper, or ytterbium can be used.

The matrix resin used in the fiber-reinforced composite material constituting the skin material and the core material is not particularly limited. When a thermosetting resin is used as the matrix resin, unsaturated polyester resin, vinyl ester resin, epoxy resin, phenol (resol type) resin, urea resin, melamine resin, maleimide resin, benzoxazine resin, or the like can be preferably used. The thermosetting resin may include multiple types of the above-described thermosetting resins. Among them, epoxy resin is particularly preferred from the viewpoint of mechanical properties and heat resistance of the molded product. The epoxy resin is preferably included as a major component of the resins used in order to achieve its excellent mechanical properties. Specifically, the epoxy resin is preferably included in an amount of at least 60% by weight of the total mass of the resin composition. Examples of the thermoplastic resin used as the matrix resin include, but not limited thereto, thermoplastic resins selected from crystalline resins, for example, “polyesters such as polyethylene terephthalate (PET), poly butylene terephthalate (PBT), polytrimethylene terephthalate (PTT), polyethylene naphthalate (PEN), liquid crystalline polyester: polyolefins such as polyethylene (PE), polypropylene (PP), polybutylene: polyoxymethylene (POM): polyamide (PA): polyarylene sulfides such as polyphenylene sulfide (PPS): polyketone (PK); polyether ketone (PEK): polyether ether ketone (PEEK): polyether ketone ketone (PEKK): polyether nitrile (PEN); fluorine-based resins such as polytetrafluoroethylene: liquid crystalline polymer (LCP)”: amorphous resins such as “styrene-based resin, as well as polycarbonate (PC), polymethyl methacrylate (PMMA), polyvinyl chloride (PVC), polyphenylene ether (PPE), polyimide (PI), polyamide imide (PAI), polyether imide (PEI), polysulfone (PSU), polyether sulfone, polyarylate (PAR)”; in addition, phenol-based resin, phenoxy resin, and further polystyrene-based, polyolefin-based, polyurethane-based, polyester-based, polyamide-based, polybutadiene-based, polyisoprene-based, fluorine-based resin, and acrylonitrile-based thermoplastic elastomers; and copolymer and modified polymer thereof. Among them, polyolefins are preferably used from the viewpoint of lightness of the resulting molded article, polyamides are preferably used from the viewpoint of strength, amorphous resins such as polycarbonates and styrene-based resins are preferably used from the viewpoint of surface quality, polyarylene sulfides are preferably used from the viewpoint of heat resistance, polyether ether ketone is preferably used from the viewpoint of continuous service temperature, and further fluorine-based resins are preferably used from the viewpoint of chemical resistance. The thermoplastic resin may include multiple types of the above-described thermoplastic resins. Alternatively, a mixture of the above-described thermosetting resin and the above-described thermoplastic resin may be used. In the present invention, the matrix resin is called a thermoplastic resin when its main component (a component accounting for over 50% by weight of 100% by weight of the entire matrix) is a thermoplastic resin, and called a thermosetting resin when its main component is a thermosetting resin.

Although different matrix resins may be used for the fiber-reinforced composite material that constitutes the skin material and the core material, the same type of resins are more preferably used from the viewpoint of enhancing the bonding strength of the skin material and the core material.

### [Core Material]

First, the core material will be explained. The core material in the present invention is a plate-like fiber-reinforced composite material member having a portion (core forming part) formed into a shape in which wavy corrugations extend unidirectionally or multidirectionally and a flat plate-like portion (core peripheral part) surrounding the core forming part. The term “plate-like” used herein means a shape in which the thickness of the core material itself is approximately constant, ignoring the three-dimensional shape of the corrugation. The term approximately constant used herein means that, for example, when the thickness is measured at 10 arbitrary positions in total of the core material, a coefficient of variation of the thickness calculated as the standard deviation of thickness/the average value of thickness is 0.5 or less. The wavy corrugation can be formed by the core material which is a plate-like fiber-reinforced composite material curving or bending in a thickness direction of the sandwich structure, and the wavy corrugation is formed, so that the apparent thickness of the material exceeds the thickness of the plate-like member itself, when placed horizontally. Here, an aspect of the wavy corrugation includes “curved” or “bent” state, where “curved” means a state in which the surface of the fiber-reinforced composite material is bent to form a curved surface, and “bent” means a state in which the surface of the fiber-reinforced composite material is bent to form an angle.

In the core material used in the present invention, a form other than wavy corrugation may be formed in the core forming part adjacent to the core peripheral part. Examples of such a form includes a structure in which tops (or bottoms) of the wavy corrugation is linearly dented when viewed in cross-section perpendicular to the ridge line of the corresponding core forming part.

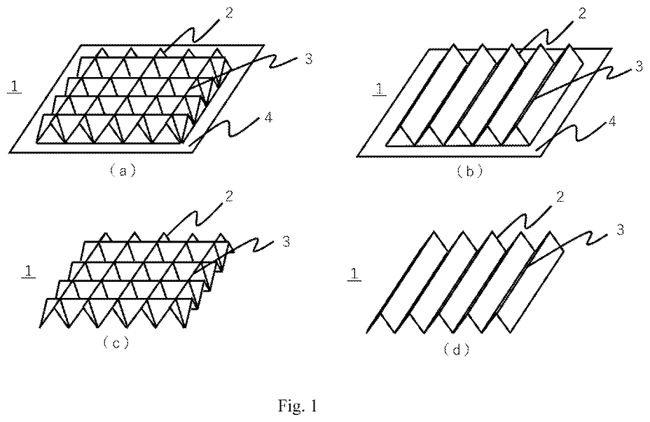

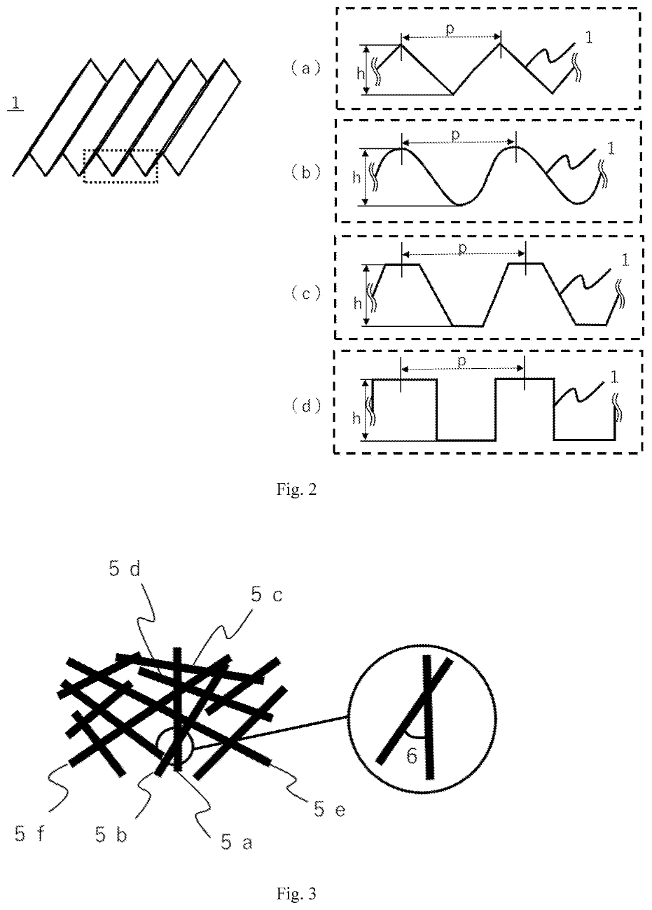

An example of a core material having wavy corrugations is illustrated in FIG. 1. FIG. 1(a) and FIG. 1(b) illustrate examples of the core material. FIG. 1(a) illustrates an example in which wavy corrugations 2 extend in two directions (in this example, the line along the tops of the corrugations, that is, the ridge lines 3 are orthogonal to each other), and FIG. 1(b) illustrates an example in which wavy corrugations 2 extend unidirectionally. Both examples have a flat plate-like portion (core peripheral part 4) surrounding the core forming part. FIG. 1(c) is a partial diagram of the core forming part extracted from FIG. 1(a), showing that the core material 1 has bending parts 3 which are orthogonal to each other and periodic in two directions, and has grid-like wavy corrugations 2 in which lines (ridge line) along the tops of the bending part 3 extend in two directions. FIG. 1(d) is a partial diagram of the core forming part extracted from FIG. 1(b), showing that the core material 1 has bending parts 3 which are unidirectionally periodic, and has wavy plate-like corrugations 2 in which lines (ridge lines) along the tops of the bending part 3 extend unidirectionally. The core peripheral part does not necessarily have to be formed around the entire periphery of the core forming part, but may be in a form where the core peripheral part is partially absent.

The core material used in the present invention has corrugations that can be formed by curving or bending a sheet of plate-like material, and those that cannot be formed from a sheet of plate-like material such as honeycomb structure are not considered as the core material in the present invention.

Particularly, the wavy corrugation of the core material is preferably in a unidirectionally extending shape as shown in FIG. 1(b). Such a shape is desirable because it allows the mechanical properties of the sandwich structure to be designed for each direction, resulting in a sandwich structure with the desired mechanical properties. A schematic shape of the wave shape can be specified using p [mm], which indicates a pitch of a wave in the waveform cross-section, and h [mm], which indicates a height of the wave, as shown in FIG. 2. In a region of the core material, in which wavy corrugations are formed, each of the pitch, p [mm], and the height, h [mm], is approximately constant, so that the wavy corrugation of the core material has a periodic shape and develops homogeneous mechanical properties, which is preferable. Here, approximately constant means that the coefficient of variation of pitch or height is 0.2 or less. The wave shape may be a bent triangular wave shape as shown in FIG. 2(a), a curved sine wave shape as shown in FIG. 2(b), a bent trapezoidal wave shape as shown in FIG. 2(c), a bent square wave shape as shown in FIG. 2(d), or forms including both of curved forms and bent forms. In specifying the pitch p of the wave, when the position of the top of the wave is not clear as in FIG. 2(c) and FIG. 2(d), the width of the smallest unit of the corrugation form is used as a substitute for the pitch p.

Preferably, 0.3<h/(p/2)<1.0, where p [mm] represents a pitch of waves of the wavy corrugation of the core material, and h [mm] represents a height of the wavy corrugation of the core material. Such a schematic shape provides an excellent balance between the bending stiffness in the ridge line direction along the tops of waves of the core material and the bending stiffness in the direction orthogonal to the ridge line direction, in the sandwich structure. In such a case, the sandwich structure exhibits stable mechanical properties regardless of the direction in which load is applied, and can therefore exhibit high rigidity for any load.

In the preferred embodiment of the present invention, the reinforcing fibers included in the fiber-reinforced composite material constituting the core material are discontinuous reinforcing fibers. Since the reinforcing fibers included in the core material are discontinuous, it becomes easy to form a wavy corrugation having a desired three-dimensional shape. In this specification, a discontinuous reinforcing fiber means a reinforcing fiber having an average fiber length of 100 mm or less. The average fiber length of the discontinuous reinforcing fiber is preferably in a range of 2 mm or more and 20 mm or less. By setting it within this range, an excellent balance between mechanical properties and formability can be obtained. As a method of measuring the fiber length of the reinforcing fiber, when the matrix resin of the core material is a thermoplastic resin, the thermoplastic resin is dissolved using a solvent that dissolves only the thermoplastic resin, and the remaining reinforcing fibers are separated by filtration and measured by microscopy (dissolution method). When there is no solvent that dissolves the thermoplastic resin, or when the matrix resin of the core material is a thermosetting resin, a method (burn off method) may be applied, in which only the resin in a temperature range where the reinforcing fibers are prevented from losing weight upon oxidation is burned off, the reinforcing fibers are segregated, and measured by microscopy. According to this method, 100 discontinuous reinforcing fibers are randomly selected from the fiber-reinforced composite material, the length of each fiber is measured to the nearest micrometer with an optical microscope, and the average value is taken as the average fiber length.

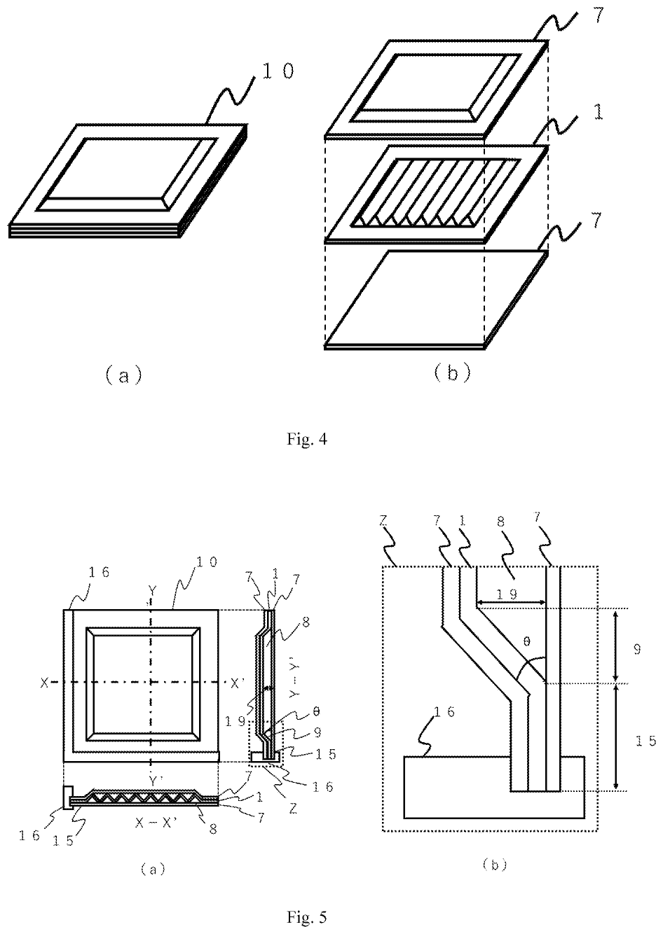

Further, the discontinuous reinforcing fibers contained in the core material are preferably oriented multidirectionally in a plane of the plate-like fiber-reinforced composite material, more preferably oriented randomly. Such a form provides isotropic formability and mechanical properties. The discontinuous reinforcing fibers being oriented multidirectionally in a plane of the plate material means that, in the plate-like fiber-reinforced composite material ignoring the three-dimensional shape of the above-described wavy corrugation, the average value of the two-dimensional orientation angle of the discontinuous reinforcing fibers described below is in a range of 30° or more and 60° or less. The average value of the two-dimensional orientation angle is more preferably in a range of 40° or more and 50° or less, and in such a case, it is determined to be randomly oriented. The two-dimensional orientation angle closer to 45° is more preferable. The average value of the two-dimensional orientation angle is measured by calculating the average value of the two-dimensional orientation angle between a randomly selected reinforcing fiber single yarn (a reinforcing fiber single yarn 5a in FIG. 3) and all the reinforcing fiber single yarns intersecting therewith (reinforcing fiber single yarns 5b to 5f in FIG. 3). When there are a large number of reinforcing fiber single yarns that intersect with the reinforcing fiber single yarn 5a, 20 intersecting reinforcing fiber single yarns are randomly selected and measured.

The measurement is repeated 5 times in total with another reinforcing fiber single yarn, and the average value of 100 two-dimensional orientation angles is taken as the average value of the two-dimensional orientation angle.

The two-dimensional orientation angle will be explained in detail with reference to FIG. 3. FIG. 3 is a schematic diagram showing the state of dispersion of the reinforcing fibers when only the reinforcing fibers are extracted from the core material and observed from the thickness direction. Focusing on the reinforcing fiber single yarn 5a the reinforcing fiber single yarn 5a intersects with the reinforcing fiber single yarns 5b to 5f. Intersecting used herein means a state in which the focused reinforcing fiber single yarn is observed to get crossed with another reinforcing fiber single yarn in the observed two-dimensional plane, and it is not necessary that the reinforcing fiber single yarn 5a and the reinforcing fiber single yarns 5b to 5f are in contact with each other in the actual core material. The two-dimensional orientation angle is an angle 6 of 0° or more and 90° or less, which is formed by two intersecting reinforcing fiber single yarns.

It is even more preferable that the discontinuous reinforcing fiber included in the core material is a monofilament. Since the reinforcing fiber is a monofilament, a core material has homogeneous physical properties in spite of its small thickness, resulting in high lightness developed. Here, the reinforcing fibers being monofilaments means that the reinforcing fiber single yarns are not bundled together but independently dispersed in the core material. The above-described two-dimensional orientation angle is measured for a reinforcing fiber single yarn arbitrarily selected from the core material and a reinforcing fiber single yarn intersecting with the reinforcing fiber single yarn, and when the percentage of the reinforcing fiber single yarn having the two-dimensional orientation angle of 1° or more is 80% or more, it is determined that the discontinuous reinforcing fiber is a monofilament. Since it is difficult to specify all the reinforcing fiber single yarns that intersect with the selected reinforcing fiber single yarn, 20 intersecting reinforcing fiber single yarns are randomly selected, and the two-dimensional orientation angle is measured. The measurement is repeated 5 times in total with another reinforcing fiber single yarn, and the percentage of the monofilament with the two-dimensional orientation angle of 1° or more is calculated.

In order to form a state in which the discontinuous reinforcing fibers contained in the core material are oriented multidirectionally and are monofilaments, as described above, the reinforcing fibers contained in the core material is preferably produced in a form of a discontinuous reinforcing fiber web. The discontinuous reinforcing fiber web is preferably a nonwoven fabric obtained by a dry method or a wet method. In nonwoven fabrics obtained by the dry or wet method, it is easy to multidirectionally or randomly disperse the discontinuous reinforcing fibers, and as a result, a core material with isotropic mechanical properties and formability can be obtained. In the discontinuous reinforcing fiber web, the reinforcing fibers may be sealed together with another component such as a binder resin. The binder resin is preferably selected from either thermoplastic resins or thermosetting resins from the viewpoint of adhesion between the resin and the reinforcing fibers, and from the viewpoint of securing handling ability by sealing only the reinforcing fibers.

The core material may have a porous structure, in which at least some of contact points where the discontinuous reinforcing fibers intersect with each other are bonded by a matrix resin, the porous structure including microporosities as portions where neither the discontinuous reinforcing fibers nor the matrix resin is present.

### [Skin Material]

Next, the skin material will be explained. The skin material is a plate-like fiber-reinforced composite material that is bonded to both sides of the core material. It is preferable that the skin material is substantially flat plate-like in the area where it is bonded to the core forming part. The term substantially flat plate-like encompasses shapes having less corrugations than the wavy corrugations of the above-described core material. More specifically, in a hypothetical cuboid that includes the skin material, bonded to the core forming part, on one side and has the smallest volume, it is preferable that the ratio L2/L1 satisfies L2/L1>10, where L1 is the length of the shortest side, and L2 is the length of the longest side. In the final sandwich structure, the skin material is bonded to both of the core forming part and the core peripheral part, so that the skin material may be processed into a three-dimensional shape.

The reinforcing fibers included in the fiber-reinforced composite material constituting the skin material are preferably continuous fibers. The continuous fibers make the sandwich structure stronger, and allow to produce a sandwich structure with excellent rigidity. In this specification, a continuous fiber means a reinforcing fiber having an average fiber length of more than 100 mm. The average fiber length can be measured with the same method described above for measuring the average fiber length of the reinforcing fibers of the core material described above.

Examples of the continuous fiber included in the skin material include a form in which continuous fibers are arranged unidirectionally, a form in which continuous fibers are oriented in multiple directions, forming a woven structure, and a form in which continuous fibers are oriented in multiple directions or randomly, forming a nonwoven fabric. From the viewpoint of isotropy of mechanical properties, a structure in which unit layers forming the above-described form are laminated is also preferred.

### [Interspace]

The sandwich structure in the present invention includes the skin material bonded to the wavy corrugations of the core material at the tops and bottoms thereof, and has spaces as interspaces surrounded by the core material and the skin material. Such a form allows the sandwich structure to minimize the weight of the core material to be used while having a sandwich structure with excellent bending stiffness, and thus both mechanical properties and lightness can be achieved. The present invention does not preclude an aspect in which the interspace is filled with a material different from the skin material and the core material, but from the viewpoint of lightness, the density of such a material is preferably 1.0 g/cm³ or less.

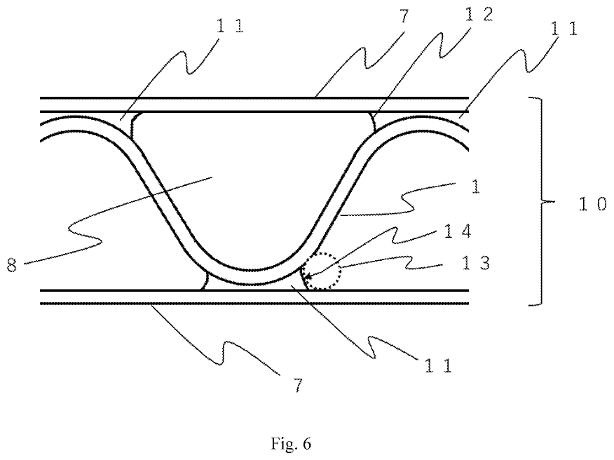

The interspaces will be explained in more detail with reference to FIG. 4 and FIG. 5. FIG. 4(a) shows an appearance of an example of the sandwich structure 10 of the present invention. FIG. 4(b) is an exploded diagram of the sandwich structure 10 of FIG. 4(a), and shows the core material 1 and the skin material 7 constituting the sandwich structure. FIG. 5(a) shows a projection diagram of the sandwich structure 10 of FIG. 4(a) when viewed from the thickness direction, and cross-sectional diagrams in the thickness direction of the sandwich structure 10 along X-X′ and Y-Y′. The sandwich structure 10 has interspaces 8 formed between the core material 1 and the skin material 7. When the core forming part of the core material 1 is in a form in which wavy corrugations extend unidirectionally, the interspaces 8 in the core forming part are tunnel-like, and have a longitudinal direction corresponding to the direction along which the tunnel extends. In FIG. 5(a), the direction along Y-Y′ corresponds to the longitudinal direction of the tunnel-like interspace 8. FIG. 5(b) is an enlarged diagram of a region indicated by Z in FIG. 5(a).

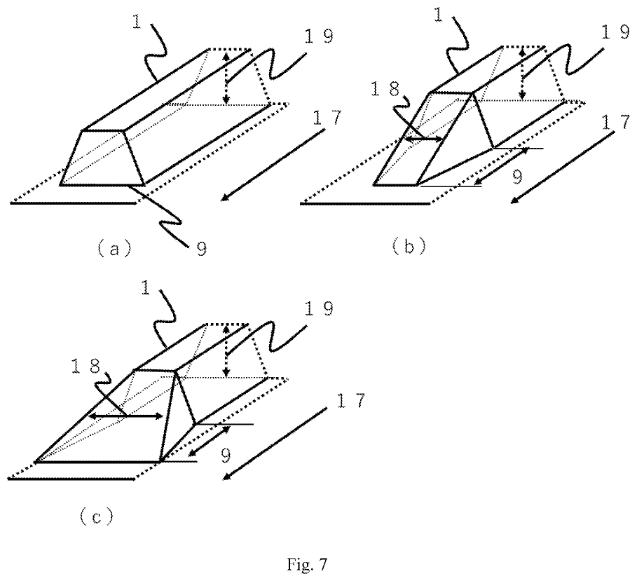

In the sandwich structure of the present invention, the skin material 7 and the core material 1 may be directly bonded to each other, or may be bonded through a resin material. In this case, it is preferable that the resin material 11 be placed and bonded so as to fill the space between the skin material and the core material near the bonding part between the skin material and the core material. FIG. 6 illustrates the resin material 11 placed to fill the space between the skin material and the core material. Such a form is desirable because it allows a fillet structure 12 to be formed with the resin material 11 near the bonding part where the skin material and the core material are bonded, which suppresses the concentration of load near the bonding part, resulting in improved mechanical properties as the sandwich structure. Further, since the resin material is placed to fill the space between the skin material and the core material, airtightness of the interspace included inside the sandwich structure in the present invention is enhanced, which is preferable. The resin material placed to fill the space between the skin material and the core material may be the same type of resin as the matrix resin of the skin material or the core material, or may be another resin different from them. In the present invention, when the radius 14 of the circle 13 obtained by approximating the shape of the fillet structure to a circle is 10 μm or more, it is determined that there is a resin adhered to fill the space between the skin material and the core material near the bonding part between the skin material and the core material. To be exact, it can be said that the interspace 8, in this form, is formed bordered by the resin material, in addition to the core material 1 and the skin material 7.

### [Closed End Structure]

In the sandwich structure of the present invention, two plate-like fiber-reinforced composite material members (skin materials) are bonded at the core peripheral part, through a portion of the core material to seal to prevent the interspace adjacent to the core peripheral part from contacting with an outside air (such a structure in which the interspace is sealed with two skin materials through the core material at the core peripheral part may be referred to as an “closed end structure”). Taking FIG. 5(a) as an example, the sandwich structure 10 has an interspace 8 at the core forming part, and an closed end structure 9 is provided so that the interspace 8 is closed at the end in the ridge line direction where the wavy corrugation of the core material constituting the interspace 8 is adjacent to the core peripheral part (see Y-Y′ in FIG. 5(a)). On the other hand, in this example, the skin material is intended to be bonded to the other skin material through a flat plate-like region of the core material to fit the outermost wavy corrugation in a direction orthogonal to the ridge line direction of the wavy corrugation of the core material constituting the interspace 8 (see X-X′ in FIG. 5(a)). FIG. 5(b) is an enlarged diagram of a region delineated by Z in FIG. 5(a). The closed end structure 9 is shown as a structure of the region from the position where the height 19 of the interspace 8 begins to decrease to the position where both sides of the core material are brought into contact with the skin material. The closed end structure also encompasses a case where the length of the closed end structure 9 in FIG. 5(b) is extremely small, such as the case where an external shape of the core material is as shown in FIG. 7(a) described later. Such a form prevents the opening of the interspace from being exposed at the end of the sandwich structure, thereby suppressing breakage starting from the opening. It also prevents foreign matter from entering the inside of the sandwich structure during manufacturing and use of the sandwich structure, while the sandwich structure has lightness due to the presence of interspaces. As a result, during normal use as a member for an electronic device housing, an increase in weight due to solid foreign matter entering the inside of the sandwich structure and damage to the inside of the sandwich structure can be suppressed. In addition, moisture absorption and deterioration of the core material caused by external gases entering the inside of the sandwich structure can be suppressed. Furthermore, entry of rainwater during outdoor use in rainy weather can be suppressed, for example. The core material and the skin material in contact with each other in the closed end structure may merely be in contact with each other, but it is more preferable that they are bonded, in which case they may be bonded directly or through a resin material. In the present invention, it is not necessary that all of the interspaces adjacent to the core peripheral part of the sandwich structure have an closed end structure, but it is more preferable that more than half of the interspaces adjacent to the core peripheral part have an closed end structure.

The closed end structure 9 will be explained in more detail with reference to FIG. 7. FIGS. 7(a), (b), and (c) are diagrams showing the structure of the core material in the closed end structure, and are examples in which the ridge lines of the wavy corrugations extend unidirectionally. FIG. 7(a) shows an example where the interspace having a constant height 19 of the wavy corrugation is formed so that it is abruptly closed, and FIG. 7(b) shows an example where the interspace having a constant height 19 of the wavy corrugation is formed so that the height 19 of the interspace gradually decreases toward the end in the longitudinal direction. FIG. 7(c) shows an example of the interspace having a constant height 19 of the wavy corrugation, which is formed to be closed so that the height 19 of the interspace gradually decreases toward the end in the longitudinal direction of the interspace and the contact width 18 between the core material and the skin material in the direction orthogonal to the direction 17 toward the end in the longitudinal direction of the interspace gradually increases. The form shown in FIG. 7(b) is preferable because it suppresses stress concentration on the core material in the closed end structure and has the effect of preventing breakage of the core material. Furthermore, the form shown in FIG. 7(c) is more preferable because it can increase the contact area between the core material and the skin material, thereby improving the effect of suppressing breakage due to stronger bonding between the core material and the skin material.

In the sandwich structure of the present invention, when viewed in cross-section cut out in the direction along the ridge line of the corrugation formed on the core material in the core forming part adjacent to the core peripheral part, the angle formed by the two skin materials is preferably more than 0° and 45° or less. With such an aspect, the shape change due to the closed end structure of the core material can be set to be gradual, and stress concentration in the closed end structure can be suppressed. In such a form, in order to more efficiently improve the mechanical properties of the sandwich structure, the angle formed by the two skin materials (indicated by θ in FIG. 5) is preferably 45° or less, more preferably 30° or less, and even more preferably 20° or less. The lower limit of θ may be more than 0°, but is preferably 1° or more in order to sufficiently develop rigidity of the core material, and preferably 3° or more in order to develop sufficient lightness. On the other hand, θ of less than 1°, which makes it difficult to control the shape of the closed end structure in the core material, is not preferred.

The method of forming the closed end structure is not particularly limited. For example, wavy corrugations are formed in the central part, as shown in FIG. 1(a) and FIG. 1(b), and a core material having a flat plate-like region surrounding the wavy corrugations are produced, and bonded to the skin material to form the closed end structure. Alternatively, the closed end structure may be formed by producing a core material in which the entire core material is formed only with wavy corrugations, without a flat plate-like region, as shown in FIG. 1(c) and FIG. 1(d), and bonding the resulting core material to the skin material while deforming the core material so that a flat-plate like shape is formed while sealing the interspace at the end of the core material at the time of bonding. Furthermore, the closed end structure may be formed by producing a core material in which the entire core material is formed only with wavy corrugations, without a flat plate-like region, as shown in FIG. 1(c) and FIG. 1(d), bonding the resulting core material to the skin material, and then deforming the core material and the skin material so that the wavy corrugations present in the core material are in a flat plate-like shape while pressing the end of the bonded skin/core material to seal the interspaces in another step.

In a core material including a core forming part having wavy corrugations extending unidirectionally as shown in FIG. 1(b), the skin material 7 can be placed to follow the wavy corrugations as shown in the cross-section along X-X′ in FIG. 5(c), on the outer edge side of the core forming part orthogonal to the ridge line of the wavy corrugations, to achieve bonding of two skin materials through the core material at the core peripheral part.

### [Peripheral Region]

The sandwich structure of the present invention preferably has a region where a portion of the core material (including the core peripheral part) that is not provided with wavy corrugations and two skin materials are bonded (such a region is referred to as a “peripheral region”). Such a form enables a strong bonding of the skin material to the core material in the peripheral region, which has an effect of reinforcing the edge parts of the sandwich structure. In addition, airtightness of the end of the sandwich structure can be enhanced, and the core material is reinforced with the skin material, thereby improving rigidity of the sandwich structure. The laminate structure in the peripheral region 15 is preferably provided with a constant width, preferably 3 mm or more, more preferably 5 mm or more, along the end of the sandwich structure. Such a peripheral region is preferably formed at the same time as forming the closed end structure by the above-described method.

### [Others]

In the present invention, from the viewpoint of thinness and lightness for application to a member for an electronic device housing, the average thickness of the portion of the sandwich structure corresponding to the core forming part where the closed end structure is not provided is 0.5 mm or more and 10 mm or less, more preferably 8 mm or less, still more preferably 5 mm or less, even more preferably 2 mm or less. The average thickness used herein is the average of thickness measurements at at least five points on the sandwich structure. When the average thickness is less than 0.5 mm, it is difficult to control the shape of the corrugation of the core material and the shape of the core material and the skin material that form the closed end structure. When the average thickness exceeds 10 mm, the core material and the skin materials require large deformation to form the closed end structure, and a fault to be a starting point of damage may be formed around the closed end structure, which is undesirable.

In the two skin materials, reinforcing fibers included in each of the skin materials preferably include two groups of fibers whose orientation directions are orthogonal to each other, and the orientation direction of at least one of the groups of fibers corresponds to the direction along which the waves of the corrugation of the core material extend, in the present invention. Such a form allows the core material to be efficiently reinforced with the skin material. Such a form can be easily prepared by using woven prepreg having a woven structure in which fibers are orthogonal to each other, or preparing a plurality of prepregs in which fibers are unidirectionally arranged, and laminating and integrating them while changing orientation directions of fibers, in obtaining fiber-reinforced composite material for skin materials. It is preferable to use laminates of unidirectional prepregs from the viewpoint of easy control of the laminate configuration.

In the present invention, all or some of the reinforcing fibers included in the fiber-reinforced composite material constituting the core material are preferably discontinuous carbon fibers. With such case, it becomes easy to form the corrugated shape and the closed end structure of the core material, and the carbon fibers with excellent mechanical properties are oriented in the thickness direction of the sandwich structure supporting between the upper and lower skin materials. Particularly, when the sandwich structure takes an closed end structure, the contact area between the core material and the skin material increases at the ends of the sandwich structure, and the carbon fibers oriented in the thickness direction of the sandwich structure increases, which enables more efficient transfer of load between the skin materials via the core material, reducing stress concentration at the ends of the sandwich structure and achieving the effect of suppressing breakage.

In the present invention, all or some of the reinforcing fibers included in the fiber-reinforced composite material constituting the skin material are preferably continuous carbon fibers. Such a form enables formation of the skin materials with excellent mechanical properties and lightness, resulting in a lightweight, highly rigid sandwich structure.

In the present invention, it is preferable that each of the two skin materials has an average thickness of 0.08 mm or more and 1 mm or less. Such a form provides a sandwich structure that is lightweight yet excellent in strength. The lower limit of the average thickness of the skin material is more preferably 0.10 mm or more, still more preferably 0.12 mm or more, and the upper limit is more preferably 0.8 mm or less, still more preferably 0.5 mm or less. An average thickness of less than 0.08 mm is undesirable because the skin material is likely to break at a portion of the skin material that is not bonded to the core material. An average thickness more than 1 mm is undesirable because formability of the skin material is reduced in the closed end structure portion and fiber fluctuation occurs, resulting in reduced strength of the sandwich structure.

### <Member for an Electronic Device Housing>

In this specification, the term “member for an electronic device housing” means a member that ultimately constitutes an electronic device housing by itself or when assembled together with other members, and may have other parts as long as the member includes the sandwich structure. In particular, an aspect having thermoplastic resin parts as described below is a preferred example. That is, the term “member for an electronic device housing” used herein encompasses a term referring to the sandwich structure alone, a term referring to a member used as part of electronic device housing by combining other parts with the sandwich structure, and a term referring to the electronic device housing itself.

With the sandwich structure of the present invention included in the member for an electronic device housing, the electronic device housing excellent in lightness and mechanical properties is obtained.

In a preferred aspect, the member for an electronic device housing of the present invention has a thermoplastic resin part integrated with the sandwich structure at a portion corresponding to the sandwich structure excluding the core forming part. With such a form, ease of assembly as an electronic device housing can be improved, and the closed end structure can prevent an increase in weight due to entry of the thermoplastic resin into the inside of the interspace of the sandwich structure.

A more detailed explanation with reference to FIG. 5(a) will be given below. The thermoplastic resin part 16 is integrated with the sandwich structure 10 while being in contact with the peripheral region 15 of the sandwich structure 10. The thermoplastic resin part can improve the mechanical properties of the member for the electronic device housing and the airtightness of the internal interspace in a form provided so as to cover an end of the sandwich structure (an end of the peripheral region 15, when the sandwich structure has a peripheral region 15), or more preferably, in a form provided to surround the end along its periphery. The thermoplastic resin part 16 is not illustrated in FIG. 4(a) and FIG. 4(b).

Such thermoplastic resin part is preferably a part integrated with the sandwich structure by injection molding. In the present invention, when such a thermoplastic resin part is integrated with the sandwich structure by injection molding, the presence of the closed end structure prevents the injected thermoplastic resin from entering the interspace. Accordingly, the weight of the final member for the electronic device housing or electronic device housing can be prevented from increasing due to the excessive thermoplastic resin.

Examples of thermoplastic resin constituting the thermoplastic resin part include polyethylene terephthalate (PET), polybutylene terephthalate (PBT), polytrimethylene terephthalate (PTT), polyethylene naphthalate (PEN), polyesters such as liquid crystalline polyesters, polyolefins such as polyethylene (PE), polypropylene (PP), and polybutylene, styrene-based resins, as well as polyoxymethylene (POM), polyamide (PA), polycarbonate (PC), polymethylene methacrylate (PMMA), polyvinyl chloride (PVC), polyphenylene sulfide (PPS), polyphenylene ether (PPE), modified PPE, polyimide (PI), polyamide imide (PAI), polyether imide (PEI), polysulfone (PSU), modified PSU, polyether sulfone, polyketone (PK), polyether ketone (PEK), polyether ether ketone (PEEK), polyether ketone ketone (PEKK), polyarylate (PAR), polyether nitrile (PEN), phenol resin, phenoxy resin, fluorine-based resins such as polytetrafluoroethylene, and further, thermoplastic elastomers such as polystyrene-based, polyolefin-based, polyurethane-based, polyester-based, polyamide-based, polybutadiene-based, polyisoprene-based, fluorine-based thermoplastic elastomers, copolymers, modifications thereof, and resins including at least two of them blended therein. An elastomer or rubber component may be added to improve impact resistance.

It is also preferable that the thermoplastic resin part includes discontinuous reinforcing fibers. Examples of the reinforcing fibers included in the thermoplastic resin part are not particularly limited, but include fibers that are electrically conductive by themselves, for example, metal fibers such as aluminum fibers, brass fibers, and stainless steel fibers, polyacrylonitrile-based, rayon-based, lignin-based, and pitch-based carbon fibers, and graphite fibers, and the fibers coated with conductive material thereof. In addition, insulating fibers such as glass fibers, organic fibers such as aramid fibers, PBO fibers, polyphenylene sulfide fibers, polyester fibers, acrylic fibers, polyamide fibers, and polyethylene fibers, and inorganic fibers such as silicon carbide fibers, and silicon nitride fibers, and the above-described fibers coated with electric conductors are exemplified. Examples of the method of coating electric conductors include plating (electrolytic and electroless), CVD, PVD, ion plating, and vapor deposition with metal such as nickel, ytterbium, gold, silver, copper, and aluminum, which enable formation of at least one electrically conductive layer. These fibers are used alone or in combination of at least two of them. From the viewpoint of the balance among specific strength, specific rigidity, and lightness, carbon fibers, among them, polyacrylonitrile-based carbon fibers are preferably used from the viewpoint of realizing low production cost. Further, from the viewpoint of economy, glass fibers are preferably used. From the viewpoint of the balance between mechanical properties and economy, it is also a preferable aspect that carbon fibers and glass fibers are used together.

### <Method of Manufacturing Sandwich Structure>

The sandwich structure of the present invention can be manufactured, for example, by a method including the following steps in this order: a core preparation step of preparing a plate-like fiber-reinforced composite material member (core material) having at least a portion (core forming part) formed into a shape in which wavy corrugations extend unidirectionally or multidirectionally; and a bonding step of bonding two plate-like fiber-reinforced composite materials (skin materials) on both sides of the core material, wherein in the core forming part adjacent to the core peripheral part, a processing is performed to form a structure in which two skin materials are bonded through a portion of the core material so as to seal to prevent a interspace formed between the core material and the skin material from contacting with an outside air. Such a manufacturing method is also understood as an aspect of the present invention.

### [Core Preparation Step]

The method of manufacturing the sandwich structure of the present invention includes a core preparation step of preparing a plate-like fiber-reinforced composite material member (core material) having a portion formed into a shape in which wavy corrugations extend unidirectionally or multidirectionally. Specific examples of the core preparation step are not particularly limited, and include a method in which a matrix resin of a sheet-like fiber-reinforced composite material is melted or softened by press molding using upper and lower molds having molding surfaces corresponding to the desired core material shape to follow the molding surface shape of the mold, and then the matrix resin is cured or solidified to obtain a core material that is a plate-like fiber-reinforced composite material having corrugations. Another exemplary method is a method of molding by a so-called corrugating processing, in which two rotating rolls with a specific surface shape are placed opposite each other, and the sheet-like fiber-reinforced composite material is passed between the two rotating rolls to follow the surface shape of the rotating rolls, thereby forming corrugations. Still another exemplary method is a method in which a resin material including reinforcing fibers is extrusion molded, thereby forming a fiber-reinforced composite material having a desired cross-sectional shape to obtain a core material.

### [Bonding Step]

In the bonding process, skin materials, which are fiber-reinforced composite materials, are bonded to both sides of the core material prepared as described above. Specific examples of the bonding step are not particularly limited, but include a method in which the skin material and the core material are overlapped and press-molded. In this event, the matrix resin of the skin material and/or core material can be softened or melted by heat pressing, and then the matrix resin can be cured or solidified to perform bonding. Alternatively, the skin material and the core material can be bonded by separately placing a resin material serving as an adhesive between the skin material and the core material followed by press molding. When the matrix resin included in the skin material is a thermosetting resin, the thermosetting resin does not necessarily have to be cured at the beginning of the bonding step, and the bonding step may be performed using an uncured prepreg.

As long as the core preparation step and the bonding step are performed in this order, another step may be included between the two steps.

In the bonding step, it is preferable to provide an additional resin material between the skin material and the core material and press-mold them so that the additional resin material straddles the skin material and the core material for bonding. In the bonding step, it is also preferable to press-mold the skin material and the core material so that at least one of the matrix resins contained in the skin material and the core material straddles between the skin material and the core material for bonding. By bonding in this manner, the skin material and the core material can be tightly bonded through an additional resin material or matrix resin at the same time as the skin material and core material are bonded in the bonding step. In addition, the above-described fillet structure is formed near the bonding part, which provides excellent mechanical properties and allows formation of highly airtight interspaces.

### [End Shape Processing]

In the manufacturing method of the sandwich structure, the sandwich structure is processed to form a structure in which two skin materials are bonded together at the core peripheral part through a portion of the core material so that the interspace adjacent to the core peripheral part is sealed and prevented from contacting with the outside air (such processing is referred to as “end shape processing”).

In a core material including a core forming part having wavy corrugations extending unidirectionally as shown in FIG. 1(b), the skin material 7 can be placed to follow the wavy corrugations as shown in the cross-section along X-X′ in FIG. 5(a), on the outer edge side of the core forming part orthogonal to the ridge line of the wavy corrugations, to achieve bonding of two skin materials through the core material at the core peripheral part.

The end shape processing may be performed on the core material and the skin material separately or simultaneously. When performed separately, processing of the core material is preferably performed together with the core preparation step. That is, when molding the core material, it is preferable to design the side shape of the portion molded into a three-dimensional shape in advance so that the end of the interspace is closed when it is finally bonded to the skin material. By performing the end shape processing together with the core preparation step, the shape of the closed end structure can be easily controlled. Specifically, in the core preparation step, as shown in FIG. 1(a) and FIG. 1(b), a core material is produced which has a flat plate region 4, not formed into a three-dimensional shape, around a region where the wavy corrugations 2 are formed, and then the core material is bonded thereto, to obtain a sandwich structure having a closed end structure.

When performed simultaneously for the core material and the skin materials, it is also preferable to perform the end shape processing after the bonding step. This method has few restrictions on the shape of the core material used, and can be applied to core materials having any three-dimensional shape. Specific examples include a method in which a core material whose appearance is as shown in FIG. 1(c) and FIG. 1(d) is produced in the core preparation step, and then the skin material and the core material are bonded in the bonding step to produce a sandwich structure, and after that, the sandwich structure is pressed along its end.

For example, after a core material and two flat plate-like skin materials are bonded at the tops or bottoms of the corrugations of the core material, the edges of the portion, in which wavy corrugations of the core material are provided, on the ridge line side of wavy corrugations, including the edge portion, are pressed to form portions so that some of the portions have gradually decreasing height in a sloping shape, and the edge portion is pressed to have a flat plate-like shape.

In particular, in the bonding step, it is preferable to bond the laminate of the core material and the skin material by press molding and to perform the end shape processing during the press molding. Such a form allows the bonding step and end shape processing to be performed simultaneously, achieving excellent mass productivity.

### [Injection Step]

It is preferable that a method of manufacturing a member for an electronic device housing of the present invention further includes an injection step of injecting a thermoplastic resin to a portion corresponding to a sandwich structure excluding the core forming part to form a thermoplastic resin part integrated with the sandwich structure. Such a form prevents the injection material from entering the inside of a member for an electronic device housing during injection molding of the injection material into a closed end structure, and enables production of the member for an electronic device housing which has lightness, high rigidity, and is easy to assemble. Further, the injection material is provided in contact with the closed end structure, so that the injection material provides an effect of further improving airtightness of the closed end structure.

### EXAMPLES

Hereinafter, the present invention will be further described in detail in Examples.

### <Evaluation Method>

### (1) Fiber Length of Reinforcing Fiber Included in Fiber-Reinforced Composite Material Constituting Core Material

One hundred reinforcing fibers were randomly selected from a carbon fiber nonwoven fabric described below, and their lengths were measured to the nearest 1 μm using an optical microscope, and the average value of the fiber lengths was calculated and taken as the average fiber length of the core material.

### (2) Two-Dimensional Orientation Angle of Reinforcing Fiber Included in Fiber-Reinforced Composite Material Constituting Core Material

The surface of the plate-like part for the core material described below was observed with a microscope, one reinforcing fiber single yarn was randomly selected, and the two-dimensional orientation angle with another reinforcing fiber single yarn intersecting with the reinforcing fiber single yarn was measured by image observation. As the two-dimensional orientation angle, an angle of 0° or more and 90° or less (acute angle) of the two angles formed by the two intersecting reinforcing fiber single yarns was employed. The number of measured two-dimensional orientation angles per one reinforcing fiber single yarn was n=20. The same measurements were made with four single yarns of different reinforcing fibers from the above measurements, and when the percentage of two-dimensional orientation angles of 1° or more out of a total of 100 measured two-dimensional orientation angles was 80% or more, the reinforcing fibers were judged to be monofilaments. Furthermore, the reinforcing fibers were determined to be oriented multidirectionally, when the average value of the two-dimensional orientation angle measured for a total of 100 single yarns was in a range of 30° or more and 60° or less.

### (3) Dimension of Corrugated Plate-Like Core Material

A cross-section perpendicular to the direction along the wave tops (waveform cross-section) in the corrugated plate-like core material was observed with an electron microscope, an interval between the tops of the wave shape was measured at five locations, and the average value was taken as a pitch p [mm] of the wave. In addition, a height of the wave was measured at five locations in the same cross-section, and the average value was taken as a height h [mm] of the wave.

### (4) Average Thickness of Sandwich Structure

In the sandwich structure obtained in Examples, the thickness of the sandwich structure was measured at five random points from the part corresponding to the core forming part where the closed end structure was not provided, and the average value was taken as the average thickness of the sandwich structure.

### (5) Fillet Radius Formed by Resin Adhered to Fill Space Between Skin Material and Core Material

In the sandwich structure obtained in Examples, the above-described waveform cross-section was observed with an electron microscope, the shape of the fillet formed by the resin adhered to fill the space between the skin material and the core material was approximated by a circle, and the radius of the circle was measured. Similar measurements were made for a different fillet structure at a total of five locations, and the average value was taken as the fillet radius.

### (6) Weight Evaluation

The weight of the sandwich structure obtained in Examples was measured using an electronic balance.

### (7) Mechanical Evaluation

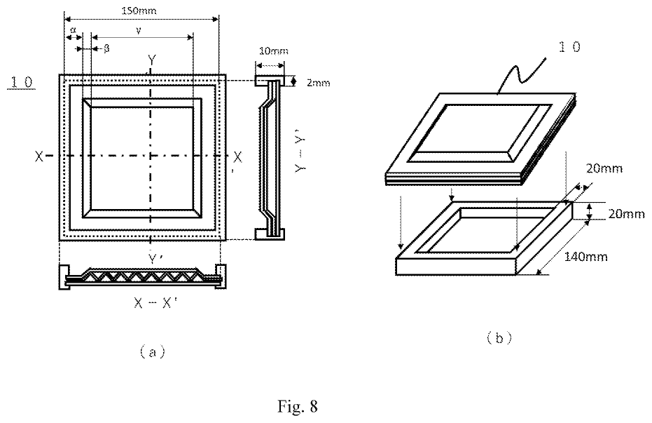

The “Instron” (registered trademark) 5565 universal testing machine (manufactured by Instron Japan Co., Ltd.) was used as a testing machine, and a sandwich structure obtained in Example was placed on a lower indenter having a square-shaped inner recess, 100 mm on side, so that its center is aligned with the center of the lower indenter, and its sides are parallel to the sides of the lower indenter, as shown in FIG. 8(b). A load was gradually applied from above using a cylindrical upper indenter with a plane area of 10 mm² at the center, and a displacement at 50 N load minus a displacement at 0.1 N load (at the start of contact) was measured as the amount of deflection [mm]. The withstanding load was investigated when the load was applied up to 300 N.

### <Production of Materials>

### [Epoxy Resin Film]

Polyvinyl formal (“VINYLEC (registered trademark)” K, manufactured by Chisso Corporation): 5 parts by mass was heated and kneaded with epoxy resins (manufactured by Japan Epoxy Resin Co., Ltd., “Epikote (registered trademark)” 828:30 parts by mass, “Epikote (registered trademark)” 1001:35 parts by mass, “Epikote (registered trademark)” 154:35 parts by mass) by a kneader to homogeneously dissolve polyvinyl formal, then a hardener dicyandiamide (DICY7, manufactured by Japan Epoxy Resin Co., Ltd.): 3.5 parts by mass and a hardener 4,4-methylenebis (phenyldimethylurea) (PTI Company Limited “Omicure” (registered trademark) 52): 7 parts by mass were kneaded by a kneader to prepare an uncured epoxy resin composition. From this, an epoxy resin film with an areal weight of 30 g/m² was produced using a knife coater.

### [Fiber-Reinforced Composite Material for Skin Material (Prepreg 1)]

Carbon fiber bundles with a total of 12,000 single yarns were obtained from copolymers mainly containing polyacrylonitrile by spinning, sintering processing, and surface oxidation processing. As for properties, the carbon fiber bundle had a tensile modulus of 220 GPa measured in accordance with JIS R7608 (2007), and a circular cross-section with a monofilament diameter of 7 μm. A sheet with carbon fiber bundles oriented unidirectionally was prepared, epoxy resin films were layered on both sides of the sheet, and heated and pressed to impregnate the sheet with the epoxy resin, thereby obtaining a prepreg 1 in which the mass of carbon fibers per unit area was 125 g/m², a fiber volume fraction was 60% and a thickness was 0.125 mm.

### [PP Resin Film]

Polypropylene resin film (manufactured by Toray Advanced Film Co., Ltd.; “TORAYFAN” (registered trademark) NO3701J; thickness, 40 μm).

### [PA Resin Film]

Nylon resin film (manufactured by Toray Advanced Film Co., Ltd.; “RAYFAN” (registered trademark) NO1401: thickness, 40 μm).

### [Carbon Fiber Nonwoven Fabric]

Carbon fiber bundles with a total of 12,000 single yarns were obtained from copolymers mainly containing polyacrylonitrile by spinning, sintering processing, and surface oxidation processing. As for properties, the carbon fiber bundle had a tensile modulus of 220 GPa measured in accordance with JIS R7608 (2007), and a circular cross-section with a monofilament diameter of 7 μm. The above-described carbon fiber bundle was used, cut into 5 mm lengths with a cartridge cutter to obtain chopped carbon fibers. A dispersion with a concentration of 0.1% by mass composed of water and a surfactant (polyoxyethylene lauryl ether (trade name) manufactured by NACALAI TESQUE, INC.) was prepared, and the dispersion and chopped carbon fibers were used to produce a carbon fiber base material. The manufacturing equipment includes, as a dispersion tank a cylindrical container with a diameter of 1,000 mm having a shut-off cock at the bottom of the container, and a linear transport unit (inclination angle, 30°) connecting the dispersion tank and the papermaking tank. A stirrer is attached to an opening on the top surface of the dispersion tank, and chopped carbon fibers and a dispersion (dispersion medium) can be introduced through the opening. The papermaking tank is equipped with a mesh conveyor having a papermaking surface with a width of 500 mm at the bottom, and a conveyor capable of transporting a carbon fiber base material (papermaking base material) is connected to the mesh conveyor. Papermaking was performed at a carbon fiber concentration of 0.05% by mass in the dispersion. The carbon fiber base material subjected to papermaking was dried in a drying oven at 200° C. for 30 minutes to obtain a carbon fiber nonwoven fabric in which orientation directions of the carbon fiber single yarns were multidirectionally dispersed. In the carbon fiber nonwoven fabric, the mass of carbon fibers per unit area was 25 g/m².

### [Plate-Like Part for Core Material 1]

PP resin film and carbon fiber nonwoven fabric were used, laminated in the order of [carbon fiber nonwoven fabric/PP resin film/carbon fiber nonwoven fabric], and pressure of 5 MPa was applied at a temperature of 200° C. for 2 minutes to produce a plate-like part for core material 1 in which the carbon fiber nonwoven fabric was impregnated with resin of the PP resin film.

### [Plate-Like Part for Core Material 2]

PA resin film and carbon fiber nonwoven fabric were used, laminated in the order of [carbon fiber nonwoven fabric/PA resin film/carbon fiber nonwoven fabric], and pressure of 5 MPa was applied at a temperature of 260° C. for 2 minutes to produce a plate-like part for core material 2 in which the carbon fiber nonwoven fabric was impregnated with resin of the PA resin film.

### [Resin Material for Injection 1]

Long fiber pellets (TLP1040 manufactured by Toray Industries, Inc.) in which the matrix resin is a polyamide-based resin and carbon fiber content is 20% by weight.

### [Resin Material for Injection 2]

Pellets (CM1001G-20 manufactured by Toray Industries, Inc.) in which the matrix resin is a polyamide-based resin and glass fiber content is 20% by weight.

### <Molding Step>

### [Core Preparation Step 1]

The plate-like part for core material 1 or 2 was press-molded using upper and lower molds having the desired molding surface shape under the molding conditions listed in Table 2, and after molding the plate-like part for core material 1 or 2 into a three-dimensional shape, the mold temperature was lowered to room temperature and a core material was obtained by demolding. The molding temperature in Table 2 refers to a molding surface temperature of the molds, and the molding pressure refers to a press pressure.

### [Core Preparation Step 2]

The plate-like part for core material 1 or 2 was heated by an IR heater, and then cooled while being passed between a pair of rotating rolls having a desired surface shape and allowing to follow the surfaces of the rotating rolls, thereby molding into a three-dimensional shape to obtain a core material. The molding temperature in Table 2 is a surface temperature of the plate-like part for core material 1 or 2 after heated by an IR heater, and the molding pressure refers to a pressure applied to the plate-like part for core material 1 or 2 by the rotating rolls.

### [Bonding Step 1]

A laminate in which prepreg 1 laminate/core material/prepreg 1 laminate were laminated in this order was molded by hot press molding, so that the matrix resin of prepreg 1 was cured, and the matrix resin contained in the core material was softened or melted. Thereafter, the skin material and the core material were cooled to room temperature while they are in contact with each other to solidify the matrix resin of the core material, thereby bonding the skin material and the core material. Note that the molding temperature in Table 2 refers to a molding surface temperature of the press machine, and the molding pressure refers to a molding pressure applied to the skin material and the core material.

### [Bonding Step 2]

A laminate in which prepreg 1 laminate/epoxy resin film/core material/epoxy resin film/prepreg 1 laminate were laminated in this order was hot pressed, so that the matrix resin of prepreg 1 was cured, and the epoxy resin film was cured as an adhesive to bond the skin material and the core material. Note that the molding temperature in Table 2 refers to a molding surface temperature of the press machine, and the molding pressure refers to a molding pressure applied to the skin material and the core material.

### [Injection Step 1]

The sandwich structure produced through the core preparation step and the bonding step was inserted into a mold for injection molding, and a thermoplastic resin part having a peripheral frame portion, a boss, a rib, and a hinge portion was injection-molded to the inserted sandwich structure to produce a member for an electronic device housing of the present invention. Injection molding was performed using a J350EIII injection molding machine manufactured by JAPAN STEEL WORKS, LTD. and the cylinder temperature was set at 280° C.

### Example 1

By [Core preparation step 1] using the plate-like part for core material 1, a core material was produced having an appearance shown in FIG. 1(b) and the wave shape shown in FIG. 2(c), and characteristics shown in FIG. 7(a) at the end of the wavy corrugations. Next, the two prepregs 1 were stacked so that the fiber orientation directions were orthogonal to each other to obtain a prepreg 1 laminate. After that, the prepreg 1 laminate/core material/prepreg 1 laminate were laminated in this order to make a laminate, and the skin material and the core material were bonded by [Bonding step 1] to obtain a square-shaped sandwich structure, 150 mm on side. Note that, at the contact surface between the prepreg 1 laminate and the core material, the layers were laminated so that the fiber orientation direction of the prepreg 1 laminate and the direction along the tops of the wave shape were orthogonal to each other. Furthermore, the core shape in the closed end structure had the characteristics shown in FIG. 7(a). Details of the obtained sandwich structure are shown in Table 1. Furthermore, the dimensions of the molded sandwich structure are shown in FIG. 8(a).

The obtained sandwich structure was checked, and the peripheral region had a laminate structure including layers composed of fiber-reinforced composite materials constituting the skin materials and a layer composed of a fiber-reinforced composite material constituting the core material. A direction along which the tops of the waves of the core material were aligned, or a direction perpendicular to the direction along which the tops of the waves were aligned, coincided with the orientation direction of the reinforcing fibers included in the skin material.

Weight evaluation and mechanical evaluation were performed using the resulting sandwich structure.

### Example 2

The sandwich structure was produced in the same manner as in Example 1, except that the core material was produced in [Core preparation step 1] so that the end shape of the corrugation part of the core material had the characteristics shown in FIG. 7(b). As a result, the core shape in a closed end structure had the characteristics shown in FIG. 7(b).

Weight evaluation and mechanical evaluation were performed using the resulting sandwich structure.

### Example 3

The sandwich structure was produced in the same manner as in Example 1, except that the core material was produced in [Core preparation step 1] so that the end shape of the corrugation part of the core material had the characteristics shown in FIG. 7(c). As a result, the core shape in a closed end structure had the characteristics shown in FIG. 7(c).

Weight evaluation and mechanical evaluation were performed using the resulting sandwich structure.

### Example 4

A sandwich structure was produced in the same manner as in Example 3, except that the wave pitch and wave height of the core material were changed as shown in Table 1. As a result, the core shape in a closed end structure had the characteristics shown in FIG. 7(c).

Weight evaluation and mechanical evaluation were performed using the resulting sandwich structure.

### Example 5

A sandwich structure was produced in the same manner as in Example 4, except that a core material having a wave shape as shown in FIG. 2(b) was produced by [Core preparation step 1] using the plate-like part for core material 1. As a result, the core shape in a closed end structure had the characteristics shown in FIG. 7(c).

Weight evaluation and mechanical evaluation were performed using the resulting sandwich structure.

### Example 6

[Injection step 1] was further performed on the sandwich structure produced in the same manner as in Example 5, and the resin material for injection 1 was injection-molded so as to be in contact with the closed end structure, and thermoplastic resin parts were added, thereby producing a member for an electronic device housing.

In this member for an electronic device housing, no injection-molded thermoplastic resin parts penetrated into the interspaces and no other foreign matter was found in the interspaces.

Weight evaluation and mechanical evaluation were performed using the resulting member for an electronic device housing.

### Example 7

A member for an electronic device housing was produced in the same manner as in Example 6, except that the wave pitch and wave height of the core material were changed as shown in Table 1.

In this member for an electronic device housing, no injection-molded thermoplastic resin parts penetrated into the interspaces and no other foreign matter was found in the interspaces.

Weight evaluation and mechanical evaluation were performed using the resulting member for an electronic device housing.

### Example 8

A member for an electronic device housing was produced in the same manner as in Example 6, except that the wave pitch and wave height of the core material were changed as shown in Table 1.

In this member for an electronic device housing, no injection-molded thermoplastic resin parts penetrated into the interspaces and no other foreign matter was found in the interspaces.

Weight evaluation and mechanical evaluation were performed using the resulting member for an electronic device housing.

### Example 9

A member for an electronic device housing was produced in the same manner as in Example 6, except that the wave pitch and wave height of the core material were changed as shown in Table 1.

In this member for an electronic device housing, no injection-molded thermoplastic resin parts penetrated into the interspaces and no other foreign matter was found in the interspaces.

Weight evaluation and mechanical evaluation were performed using the resulting member for an electronic device housing.

### Example 10

A member for an electronic device housing was produced in the same manner as in Example 6, except that [Bonding step 2] was performed instead of [Bonding step 1], and the resin material for injection 2 was used in [Injection step 1].

The obtained member for an electronic device housing was checked, and the peripheral region of the sandwich structure had a laminate structure including layers composed of fiber-reinforced composite materials constituting the skin materials and a layer composed of a fiber-reinforced composite material constituting the core material. Furthermore, no thermoplastic resin parts penetrated into the interspaces in the sandwich structure, and no other foreign matter was found in the interspaces. In addition, at the bonding part between the skin material and the core material, the epoxy resin adhered to fill the space between the skin material and the core material, and a fillet structure was formed by the epoxy resin.

Weight evaluation and mechanical evaluation were performed using the resulting member for an electronic device housing.

### Example 11

A member for an electronic device housing was produced in the same manner as in Example 10, except that in [Bonding step 1], the prepreg 1 laminate was rotated 45° around the stacking direction taken as an axis with respect to the core material.

The obtained member for an electronic device housing was checked, and was found to have a laminate structure including layers composed of fiber-reinforced composite materials constituting the skin materials and a layer composed of a fiber-reinforced composite material constituting the core material along the closed end structure. In the sandwich structure, the direction along which the tops of the waves of the core material were aligned, or a direction orthogonal to the direction along which the tops of the waves were aligned, did not coincide with the orientation direction of the reinforcing fibers included in the skin material. Furthermore, no thermoplastic resin parts penetrated into the interspaces in the sandwich structure, and no other foreign matter was found in the interspaces. In addition, the epoxy resin adhered to the bonding part between the skin material and the core material, and a fillet structure was formed by the epoxy resin.

Weight evaluation and mechanical evaluation were performed using the resulting member for an electronic device housing.

### Example 12

A member for an electronic device housing was produced in the same manner as in Example 10, except that [Core preparation step 1] was performed using a plate-like part for core material 2 to produce a core material including only unidirectionally extending wavy corrugations (i.e., the appearance is as shown in FIG. 1(d)) present therein, and having a wave shape as shown in FIG. 2(c), and then, a sandwich structure was produced by [Bonding step 2] using a mold having a flat plate-like molding surface, and then, additional press molding was performed along the end of the sandwich structure, and the edge portions of the wavy corrugations were crushed and some of them were formed as flat plate-like portions to form an closed end structure. As a result, a closed end structure in which the core shape had the characteristics shown in FIG. 7(c) was formed.

The obtained member for an electronic device housing was checked, and it was found that the peripheral region had a laminate structure including layers composed of fiber-reinforced composite materials constituting the skin materials and a layer composed of a fiber-reinforced composite material constituting the core material. In the sandwich structure, the direction along which the tops of the waves of the core material were aligned, or a direction orthogonal to the direction along which the tops of the waves were aligned, coincided with the orientation direction of the reinforcing fibers included in the skin material. Furthermore, no thermoplastic resin parts penetrated into the interspaces in the sandwich structure, and no other foreign matter was found in the interspaces. In addition, the epoxy resin adhered to the bonding part between the skin material and the core material, and a fillet structure was formed by the epoxy resin.

Weight evaluation and mechanical evaluation were performed using the resulting member for an electronic device housing.

### Example 13

A member for an electronic device housing was produced in the same manner as in Example 12, except that [Core preparation step 2] was performed using a composite material plate-like part for core material 2, instead of [Core preparation step 1]. As a result, a closed end structure in which the core shape had the characteristics shown in FIG. 7(c) was formed. Mechanical evaluation was performed using the resulting member for an electronic device housing.

The obtained member for an electronic device housing was checked, and it was found that the peripheral region had a laminate structure including layers composed of fiber-reinforced composite materials constituting the skin materials and a layer composed of a fiber-reinforced composite material constituting the core material. In the sandwich structure, the direction along which the tops of the waves of the core material were aligned, or a direction orthogonal to the direction along which the tops of the waves were aligned, coincided with the orientation direction of the reinforcing fibers included in the skin material. Furthermore, no thermoplastic resin parts penetrated into the interspaces in the sandwich structure, and no other foreign matter was found in the interspaces. In addition, the epoxy resin adhered to the bonding part between the skin material and the core material, and a fillet structure was formed by the epoxy resin.

Weight evaluation and mechanical evaluation were performed using the resulting member for an electronic device housing.

### Comparative Example 1

A sandwich structure was produced in the same manner as Example 1, except that the core material produced in [Core preparation step 1] which included only unidirectionally extending wavy corrugations present therein (i.e., the appearance is as shown in FIG. 1(d)) and had wave shape as shown in FIG. 2(c), and was press-molded using a flat molding surface in [Bonding step 1]. The sandwich structure thus obtained did not have a closed end structure, and the openings of the interspaces were exposed at the end of the sandwich structure.

Weight evaluation and mechanical evaluation were performed using the resulting sandwich structure.

### Comparative Example 2

A member for an electronic device housing was produced in the same manner as Example 12, except that an additional press molding was not performed. In [Injection step 1], since the sandwich structure did not have the closed end structure, injection molding was performed on the end of the sandwich structure.

The resulting member for an electronic device housing was checked, the thermoplastic resin part penetrated into the interspaces of the member for an electronic device housing, resulting in a significant increase in weight. Further, the core material was significantly deformed at the end of the sandwich structure due to the pressure of the injection material.

Weight evaluation and mechanical evaluation were performed using the resulting member for an electronic device housing.

The results of weight evaluation and mechanical evaluation in each of Examples/Comparative Examples are summarized in Table 3.

### [Table 1-1]

TABLE 1-1

| | | | Core material | | | | | | | | |
|---|---|---|---|---|---|---|---|---|---|---|---|
| | | | | | Average of | | | | | | |
| | | | | | two- | | | | | | |
| | Skin material | | | Average | dimensional | | Height | Pitch | | | |
| | Material | Fiber | Material | fiber | orientation | State of | of wave | of wave | | Schematic | Shape |
| | used | length | used | length | angle | dispersion | h[mm] | p[mm] | h/(p/2) | shape | of top |
| Example 1 | Prepreg | Continuous | Plate-like | 5 mm | 40° | Monofilament | 1 | 3 | 0.67 | FIG. | FIG. |
| | 1 | fiber | part for | | | | | | | 1(b) | 2(c) |
| | | | core | | | | | | | | |
| | | | material 1 | | | | | | | | |
| Example 2 | Prepreg | Continuous | Plate-like | 5 mm | 40° | Monofilament | 1 | 3 | 0.67 | FIG. | FIG. |
| | 1 | fiber | part for | | | | | | | 1(b) | 2(c) |
| | | | core | | | | | | | | |
| | | | material 1 | | | | | | | | |
| Example 3 | Prepreg | Continuous | Plate-like | 5 mm | 40° | Monofilament | 1 | 3 | 0.67 | FIG. | FIG. |
| | 1 | fiber | member | | | | | | | 1(b) | 2(c) |
| | | | for core | | | | | | | | |
| | | | material 1 | | | | | | | | |
| Example 4 | Prepreg | Continuous | Plate-like | 5 mm | 40° | Monofilament | 0.8 | 6 | 0.27 | FIG. | FIG. |
| | 1 | fiber | part for | | | | | | | 1(b) | 2(c) |
| | | | core | | | | | | | | |
| | | | material 1 | | | | | | | | |
| Example 5 | Prepreg | Continuous | Plate-like | 5 mm | 40° | Monofilament | 0.8 | 6 | 0.27 | FIG. | FIG. |
| | 1 | fiber | part for | | | | | | | 1(b) | 2(b) |
| | | | core | | | | | | | | |
| | | | material 1 | | | | | | | | |
| Example 6 | Prepreg | Continuous | Plate-like | 5 mm | 40° | Monofilament | 0.8 | 6 | 0.27 | FIG. | FIG. |
| | 1 | fiber | part for | | | | | | | 1(b) | 2(b) |
| | | | core | | | | | | | | |
| | | | material 1 | | | | | | | | |
| Example 7 | Prepreg | Continuous | Plate-like | 5 mm | 40° | Monofilament | 0.8 | 4 | 0.40 | FIG. | FIG. |
| | 1 | fiber | part for | | | | | | | 1(b) | 2(b) |
| | | | core | | | | | | | | |
| | | | material 1 | | | | | | | | |
| Example 8 | Prepreg | Continuous | Plate-like | 5 mm | 40° | Monofilament | 1 | 3 | 0.67 | FIG. | FIG. |
| | 1 | fiber | part for | | | | | | | 1(b) | 2(b) |
| | | | core | | | | | | | | |
| | | | material 1 | | | | | | | | |
| Example 9 | Prepreg | Continuous | Plate-like | 5 mm | 40° | Monofilament | 1.2 | 2 | 1.20 | FIG. | FIG. |
| | 1 | fiber | part for | | | | | | | 1(b) | 2(b) |
| | | | core | | | | | | | | |
| | | | material 1 | | | | | | | | |
| Example 10 | Prepreg | Continuous | Plate-like | 5 mm | 40° | Monofilament | 0.8 | 6 | 0.27 | FIG. | FIG. |
| | 1 | fiber | part for | | | | | | | 1(b) | 2(b) |
| | | | core | | | | | | | | |
| | | | material 1 | | | | | | | | |
| Example 11 | Prepreg | Continuous | Plate-like | 5 mm | 40° | Monofilament | 0.8 | 6 | 0.27 | FIG. | FIG. |
| | 1 | fiber | part for | | | | | | | 1(b) | 2(b) |
| | | | core | | | | | | | | |
| | | | material 1 | | | | | | | | |
| Example 12 | Prepreg | Continuous | Plate-like | 5 mm | 40° | Monofilament | 0.8 | 6 | 0.27 | FIG. | FIG. |
| | 1 | fiber | part for | | | | | | | 1(d) | 2(c) |
| | | | core | | | | | | | | |
| | | | material 2 | | | | | | | | |
| Example 13 | Prepreg | Continuous | Plate-like | 5 mm | 40° | Monofilament | 0.8 | 6 | 0.27 | FIG. | FIG. |
| | 1 | fiber | part for | | | | | | | 1(d) | 2(c) |
| | | | core | | | | | | | | |
| | | | material 2 | | | | | | | | |
| Comparative | Prepreg | Continuous | Plate-like | 5 mm | 40° | Monofilament | 1 | 3 | 0.67 | FIG. | FIG. |
| Example 1 | 1 | fiber | part for | | | | | | | 1(d) | 2(c) |
| | | | core | | | | | | | | |
| | | | material 1 | | | | | | | | |
| Comparative | Prepreg | Continuous | Plate-like | 5 mm | 40° | Monofilament | 0.8 | 6 | 0.27 | FIG. | FIG. |
| Example 2 | 1 | fiber | part for | | | | | | | 1(d) | 2(c) |
| | | | core | | | | | | | | |
| | | | material 2 | | | | | | | | |

### [Table 1-2]

TABLE 1-2

| | Closed end | | | | | |
|---|---|---|---|---|---|---|
| | structure | | | | | |
| | Figure showing | Sandwich structure | | | | |
| | characteristics | Length of α | Length of β | Length of γ | Average | Fillet |
| | of shape | in FIG. 8 | in FIG. 8 | in FIG. 8 | thickness | radius |
| Example 1 | FIG. 7(a) | 10 mm | 0 mm | 130 mm | 1.4 mm | — |
| Example 2 | FIG. 7(b) | 10 mm | 10 mm | 110 mm | 1.4 mm | — |
| Example 3 | FIG. 7(c) | 10 mm | 10 mm | 110 mm | 1.4 mm | — |
| Example 4 | FIG. 7(c) | 10 mm | 10 mm | 110 mm | 1.4 mm | — |
| Example 5 | FIG. 7(c) | 10 mm | 10 mm | 110 mm | 1.4 mm | — |
| Example 6 | FIG. 7(c) | 10 mm | 10 mm | 110 mm | 1.4 mm | — |
| Example 7 | FIG. 7(c) | 10 mm | 10 mm | 110 mm | 1.4 mm | — |
| Example 8 | FIG. 7(c) | 10 mm | 10 mm | 110 mm | 1.4 mm | — |
| Example 9 | FIG. 7(c) | 10 mm | 10 mm | 110 mm | 1.4 mm | — |
| Example 10 | FIG. 7(c) | 10 mm | 10 mm | 110 mm | 1.4 mm | 50 μm |
| Example 11 | FIG. 7(c) | 10 mm | 10 mm | 110 mm | 1.4 mm | 50 μm |
| Example 12 | FIG. 7(c) | 10 mm | 10 mm | 110 mm | 1.4 mm | 50 μm |
| Example 13 | FIG. 7(c) | 10 mm | 10 mm | 110 mm | 1.4 mm | 50 μm |
| Comparative | — | — | — | — | 1.4 mm | — |
| Example 1 | | | | | | |
| Comparative | — | — | — | — | 1.4 mm | 50 μm |
| Example 2 | | | | | | |

### [Table 2]

TABLE 2

| | | | | | | | End shape | Injection |
|---|---|---|---|---|---|---|---|---|
| | Core preparation step | | | Bonding step | | | processing | step |
| | | Processing | Processing | | Processing | Processing | Timing of | Performed/Not |
| | Step | temperature | pressure | Step | temperature | pressure | performance | performed |
| Example 1 | Core | 200° C. | 5 MPa | Bonding | 180° C. | 1 MPa | Core | Not |
| | preparation | | | step 1 | | | preparation | performed |
| | step 1 | | | | | | step | |
| Example 2 | Core | 200° C. | 5 MPa | Bonding | 180° C. | 1 MPa | Core | Not |
| | preparation | | | step 1 | | | preparation | performed |
| | step 1 | | | | | | step | |
| Example 3 | Core | 200° C. | 5 MPa | Bonding | 180° C. | 1 MPa | Core | Not |
| | preparation | | | step 1 | | | preparation | performed |
| | step 1 | | | | | | step | |
| Example 4 | Core | 200° C. | 5 MPa | Bonding | 180° C. | 1 MPa | Core | Not |
| | preparation | | | step 1 | | | preparation | performed |
| | step 1 | | | | | | step | |
| Example 5 | Core | 200° C. | 5 MPa | Bonding | 180° C. | 1 MPa | Core | Not |
| | preparation | | | step 1 | | | preparation | performed |
| | step 1 | | | | | | step | |
| Example 6 | Core | 200° C. | 5 MPa | Bonding | 180° C. | 1 MPa | Core | Performed |
| | preparation | | | step 1 | | | preparation | |
| | step 1 | | | | | | step | |
| Example 7 | Core | 200° C. | 5 MPa | Bonding | 180° C. | 1 MPa | Core | Performed |
| | preparation | | | step 1 | | | preparation | |
| | step 1 | | | | | | step | |
| Example 8 | Core | 200° C. | 5 MPa | Bonding | 180° C. | 1 MPa | Core | Performed |
| | preparation | | | step 1 | | | preparation | |
| | step 1 | | | | | | step | |
| Example 9 | Core | 200° C. | 5 MPa | Bonding | 180° C. | 1 MPa | Core | Performed |
| | preparation | | | step 1 | | | preparation | |
| | step 1 | | | | | | step | |
| Example 10 | Core | 200° C. | 5 MPa | Bonding | 180° C. | 1 MPa | Core | Performed |
| | preparation | | | step 2 | | | preparation | |
| | step 1 | | | | | | step | |
| Example 11 | Core | 200° C. | 5 MPa | Bonding | 180° C. | 1 MPa | Core | Performed |
| | preparation | | | step 2 | | | preparation | |
| | step 1 | | | | | | step | |
| Example 12 | Core | 260° C. | 5 MPa | Bonding | 180° C. | 1 MPa | After | Performed |
| | preparation | | | step 2 | | | bonding | |
| | step 1 | | | | | | step | |
| Example 13 | Core | 260° C. | 5 MPa | Bonding | 180° C. | 1 MPa | After | Performed |
| | preparation | | | step 2 | | | bonding | |
| | step 2 | | | | | | step | |
| Comparative | Core | 200° C. | 5 MPa | Bonding | 180° C. | 1 MPa | Not | Not |
| Example 1 | preparation | | | step 1 | | | performed | performed |
| | step 1 | | | | | | | |
| Comparative | Core | 260° C. | 5 MPa | Bonding | 180° C. | 1 MPa | Not | Performed |
| Example 2 | preparation | | | step 2 | | | performed | |
| | step 1 | | | | | | | |

### [Table 3]

TABLE 3

Mechanical evaluation

| | | Amount of | Withstanding |
|---|---|---|---|
| | Weight evaluation | deflection | load |
| | [g] | [mm] | [N] |
| Example 1 | 20 | 0.9 | 270 |
| Example 2 | 20 | 0.9 | 290 |
| Example 3 | 20 | 0.9 | 300 |
| Example 4 | 20 | 1 | 300 |
| Example 5 | 20 | 0.95 | 300 |
| Example 6 | 35 | 0.95 | 300 |
| Example 7 | 35 | 0.75 | 300 |
| Example 8 | 36 | 0.6 | 300 |
| Example 9 | 36 | 0.8 | 300 |
| Example 10 | 37 | 0.75 | 300 |
| Example 11 | 37 | 0.85 | 300 |
| Example 12 | 37 | 0.75 | 300 |
| Example 13 | 37 | 0.75 | 300 |
| Comparative | 20 | 0.9 | 240 |
| Example 1 | | | |
| Comparative | 50 | 2 | 300 |
| Example 2 | | | |

### REFERENCE SIGNS LIST

1 Core material
2 Wavy corrugation
3 Ridge line of wavy corrugation
4 Flat plate region (core peripheral part)
5 Reinforcing fiber single yarn
6 Angle
7 Skin material
8 Interspace
9 Closed end structure
10 Sandwich structure
11 Resin material
12 Fillet structure
13 Arc approximate to fillet structure
14 Radius of arc approximate to fillet structure
15 Peripheral region
16 Thermoplastic resin part
17 Direction toward end in longitudinal direction of interspace
18 Contact width between core material and skin material
19 Height of interspace

1. A sandwich structure, comprising:
a plate-like fiber-reinforced composite material member (core material) having a portion (referred to as a “core forming part”) formed into a shape in which wavy corrugations extend unidirectionally or multidirectionally and a flat plate-like portion (referred to as a “core peripheral part”) surrounding the core forming part; and
two plate-like fiber-reinforced composite material members (skin materials) that are bonded to the core material at tops or bottoms of the corrugation thereof, have interspaces between the member and the core material at the rest of the core forming part, and are bonded through a portion of the core material so as to seal to prevent the interspace adjacent to the core peripheral part from contacting with an outside air.

2. The sandwich structure according to claim 1,
wherein the wavy corrugation is in a unidirectionally extending shape, and each of the interspaces has a tunnel-like shape.

3. The sandwich structure according to claim 1,
wherein the two skin materials are angled at an angle of more than 0° and 45° or less when viewed in cross-section cut out in a direction along a ridge line of the corrugation in the core forming part adjacent to the core peripheral part.

4. The sandwich structure according to claim 2,
wherein 0.3<h/(p/2)<1.0, where p [mm] represents a pitch of waves of the wavy corrugation, and h [mm] represents a height of the wavy corrugation.

5. The sandwich structure according to claim 1,
wherein in the two skin materials, reinforcing fibers included in each of the skin materials include two groups of fibers whose orientation directions are orthogonal to each other, and the orientation direction of at least one of the groups of fibers corresponds to the direction along which the wave of the corrugation of the core material extends.

6. The sandwich structure according to claim 1,
wherein the average thickness of the sandwich structure is 0.5 mm or more and 10 mm or less.

7. The sandwich structure according to claim 1,
wherein the average thickness of each of the skin materials is 0.08 mm or more and 1 mm or less.

8. The sandwich structure according to claim 1,
wherein the reinforcing fibers included in the fiber-reinforced composite material constituting the skin material are continuous fibers.

9. The sandwich structure according to claim 1,
wherein all or some of the reinforcing fibers included in the fiber-reinforced composite material constituting the skin material are continuous carbon fibers.

10. The sandwich structure according to claim 1,
wherein the reinforcing fibers included in the fiber-reinforced composite material constituting the core material are discontinuous fibers, and multidirectionally oriented in the core material.

11. The sandwich structure according to claim 1,
wherein the reinforcing fibers included in the fiber-reinforced composite material constituting the core material are discontinuous monofilaments.

12. The sandwich structure according to claim 1,
wherein all or some of the reinforcing fibers included in the fiber-reinforced composite material constituting the core material are discontinuous carbon fibers.

13. The sandwich structure according to claim 1,
wherein the core material and the skin material are bonded through a resin at the tops or bottoms of the wavy corrugation of the core material.

14. A member for an electronic device housing comprising the sandwich structure according to claim 1.

15. The member for an electronic device housing according to claim 14,
wherein the member further comprises a member made of a thermoplastic resin, and the member made of the thermoplastic resin is integrated with the sandwich structure at a portion corresponding to the sandwich structure excluding the core forming part.

16. A method of manufacturing a sandwich structure, comprising the following steps in this order:
a core preparation step of preparing a plate-like fiber reinforced composite material member (core material) having at least a portion (core forming part) formed into a shape in which wavy corrugations extend unidirectionally or multidirectionally; and
a bonding step of bonding two plate-like fiber-reinforced composite materials (skin materials) on both sides of the core material,
wherein in the core forming part adjacent to a flat plate-like core peripheral part surrounding the core forming part, a processing is performed to form a structure in which two skin materials are bonded through a portion of the core material so as to seal to prevent a interspace formed between the core material and the skin material from contacting with an outside air.

17. The method of manufacturing the sandwich structure according to claim 16, wherein in the bonding step, the core material and the skin material are bonded by press molding.
